(19) United States
(12) Patent Application Publication
(10) Pub. No.: US 2024/0321979 A1
(43) Pub. Date: Sep. 26, 2024

(54) INTEGRATED CIRCUIT DEVICE

(71) Applicant: SAMSUNG ELECTRONICS CO., LTD., SUWON-SI (KR)

(72) Inventors: Davin LEE, Suwon-si (KR); Hyunseung SONG, Suwon-si (KR)

(21) Appl. No.: 18/544,560

(22) Filed: Dec. 19, 2023

(30) Foreign Application Priority Data
Mar. 24, 2023 (KR) 10-2023-0038968
Jun. 8, 2023 (KR) 10-2023-0073738

(51) Int. Cl. H01L 29/417; H01L 27/092; H01L 29/06; H01L 29/423; H01L 29/775; H01L 29/786

(52) U.S. Cl. CPC H01L 29/41733; H01L 27/092; H01L 29/0673; H01L 29/41775; H01L 29/42392; H01L 29/775; H01L 29/78696

(57) ABSTRACT

An integrated circuit device includes: a substrate including a first and second device regions; a first and third fin-type active regions extending in a first direction in the first device region; a second and fourth fin-type active regions extending in the first direction in the second device region; a gate line extending in a second direction crossing the first direction in the first through fourth fin-type active regions; a first source/drain region adjacent to the gate line in the first fin-type active region; a second source/drain region adjacent to the gate line in the second fin-type active region; a first source/drain contact connected to the first source/drain region; and a second source/drain contact connected to the second source/drain region; wherein the first source/drain contact includes a first short metal plug and a first conductive barrier layer at least partially surrounding a portion of sidewalls of the first short metal plug.

### CROSS-REFERENCE TO RELATED APPLICATION

This application claims priority under 35 U.S.C. § 119 to Korean Patent Application Nos. 10-2023-0038968, filed on Mar. 24, 2023, and 10-2023-0073738, filed on Jun. 8, 2023, in the Korean Intellectual Property office, the disclosures of which are incorporated by reference herein in their entireties.

### TECHNICAL FIELD

The present inventive concept relates to an integrated circuit device.

### DISCUSSION OF THE RELATED ART

With the recent miniaturization of integrated circuit devices, it is desirable to secure not only a fast operational speed but an accuracy in operation in the integrated circuit devices. In addition, as the integration degree of integrated circuit devices increases and the size thereof decreases, the possibility of process defects occurring in the manufacturing process of the integrated circuit devices may increase. Accordingly, it is desirable to develop an integrated circuit device having a new structure which reduces the possibility of process defects occurring and increase the performance and reliability of the integrated circuit device.

### SUMMARY

According to an embodiment of the present inventive concept, an integrated circuit device includes: a substrate including a first device region and a second device region; a first fin-type active region and a third fin-type active region extending in a first horizontal direction in the first device region; a second fin-type active region and a fourth fin-type active region extending in the first horizontal direction in the second device region; a gate line extending in a second horizontal direction crossing the first horizontal direction in the first through fourth fin-type active regions; a first source/drain region arranged adjacent to the gate line in the first fin-type active region; a second source/drain region arranged adjacent to the gate line in the second fin-type active region; a first source/drain contact extending in a vertical direction in the first device region, and connected to the first source/drain region, wherein the vertical direction is substantially perpendicular to the first horizontal direction and the second horizontal direction; and a second source/drain contact extending in the vertical direction in the second device region, and connected to the second source/drain region; wherein the first source/drain contact includes a first short metal plug and a first conductive barrier layer at least partially surrounding a portion of sidewalls of the first short metal plug.

According to an embodiment of the present inventive concept, an integrated circuit device includes: a substrate including a first device region and a second device region; a first fin-type active region and a third fin-type active region extending in a first horizontal direction in the first device region; a second fin-type active region and a fourth fin-type active region extending in the first horizontal direction in the second device region; a gate line extending in a second horizontal direction crossing the first horizontal direction in the first through fourth fin-type active regions; a first source/drain region arranged adjacent to the gate line in the first fin-type active region; a second source/drain region arranged adjacent to the gate line in the second fin-type active region; a first source/drain contact extending in a vertical direction in the first device region, and connected to the first source/drain region, wherein the vertical direction is substantially perpendicular to the first and second horizontal directions; and a second source/drain contact extending in the vertical direction in the second device region, and connected to the second source/drain region; wherein the first source/drain contact includes a first short metal plug and a first conductive barrier layer at least partially surrounding a portion of sidewalls of the first short metal plug, wherein the second source/drain contact includes a long metal plug and a second conductive barrier layer at least partially surrounding sidewalls of the long metal plug, wherein the gate line includes a first gate line and a second gate line, wherein the first gate line extends in the second horizontal direction in the first device region, and the second gate line extends in the second horizontal direction in the second device region, and wherein a width, in the first horizontal direction, of the first gate line is less than a width, in the first horizontal direction, of the second gate line.

According to an integrated circuit device includes: a substrate including a first device region and a second device region; a first fin-type active region and a third fin-type active region extending in a first horizontal direction in the first device region, a second fin-type active region and a fourth fin-type active region extending in the first horizontal direction in the second device region; a gate line extending in a second horizontal direction crossing the first horizontal direction in the first through fourth fin-type active regions and including a first gate line and a second gate line; a first source/drain region arranged adjacent to the gate line in the first fin-type active region; a second source/drain region arranged adjacent to the gate line in the second fin-type active region; a first source/drain contact extending in a vertical direction in the first device region, and connected to the first source/drain region, wherein the vertical direction is substantially perpendicular to the first and second horizontal directions; a second source/drain contact extending in the vertical direction in the second device region, and connected to the second source/drain region; a first nanosheet stack including at least one short nanosheet surrounded by the first gate line at a position spaced apart in the vertical direction from the first fin-type active region; and a second nanosheet stack including at least one long nanosheet surrounded by the second gate line at a position spaced apart in the vertical direction from the second fin-type active region, wherein the first source/drain contact includes a short metal plug and a first conductive barrier layer, wherein the first conductive barrier layer surrounds a portion of sidewalls of the short metal plug, wherein the second source/drain contact includes a long metal plug and a second conductive barrier layer, wherein the second conductive barrier layer surrounds sidewalls of the long metal plug, wherein the first gate line extends in the second horizontal direction in the first device region, and the second gate line extends in the second horizontal direction in the second device region, wherein a width, in the first horizontal direction, of the first gate line is less than a width, in the first horizontal direction, of the second gate line, and wherein a width, in a second horizontal direction, of the first nanosheet is less than a width, in the second horizontal direction, of the second nanosheet stack.

### BRIEF DESCRIPTION OF THE DRAWINGS

The above and other aspects of the present inventive concept will become more apparent by describing in detail embodiments thereof, with reference to the accompanying drawings, in which:

FIG. 1 is a plan layout diagram of components of an integrated circuit device, according to an embodiment of the present inventive concept;

FIG. 2A is a cross-sectional view of components taken along line A1-A1′ in FIG. 1, and

FIG. 2B is a cross-sectional view of components taken along line B1-B1′ in FIG. 1;

FIG. 3 is an enlarged cross-sectional view of a region FX1 in FIG. 1;

FIG. 4 is an enlarged cross-sectional view of a region FX2 in FIG. 1;

FIGS. 5A, 5B, 5C, 5D, 5E, and 5F are cross-sectional views for describing a method of manufacturing an integrated circuit device, according to embodiments of the present inventive concept; and

FIG. 6 is a configuration diagram of a system including an integrated circuit device, according to an embodiment of the present inventive concept.

### DETAILED DESCRIPTION OF THE EMBODIMENTS

Hereinafter, embodiments of the present inventive concept will be described in detail with reference to the accompanying drawings. Identical reference numerals are used for the same constituent elements in the drawings, and duplicate descriptions thereof are omitted or briefly discussed.

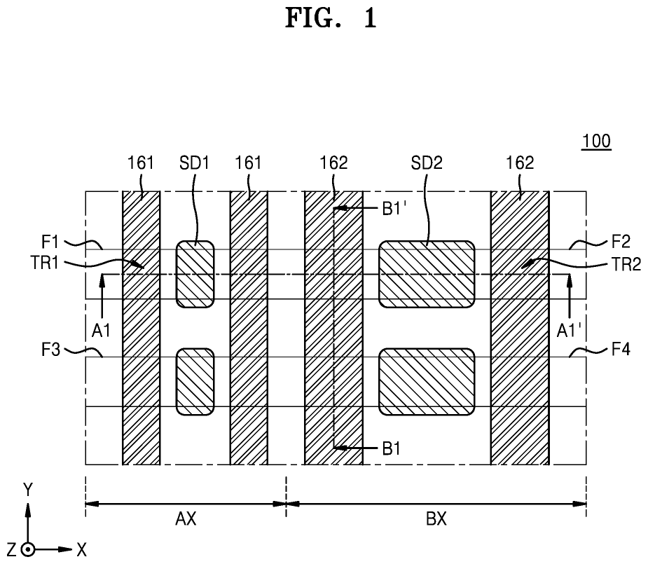

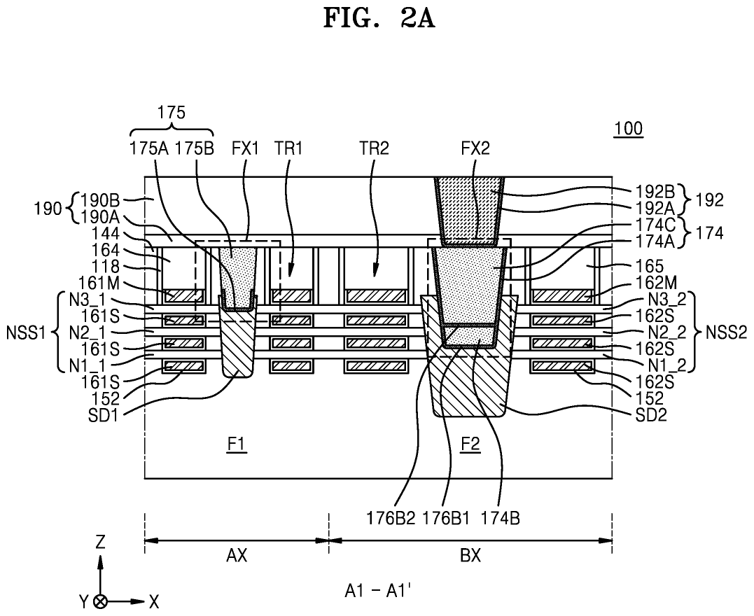

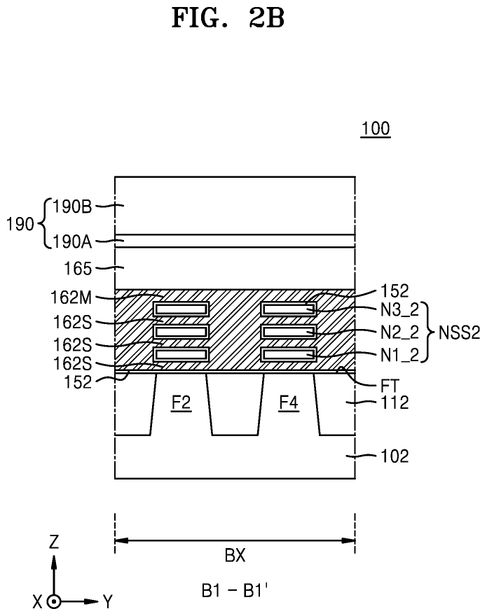

FIG. 1 is a plan layout diagram of components of an integrated circuit device 100, according to an embodiment of the present inventive concept. FIG. 2A is a cross-sectional view of components taken along line A1-A1′ in FIG. 1, and FIG. 2B is a cross-sectional view of components taken along line B1-B1′ in FIG. 1.

Referring to FIGS. 1, 2A, and 2B, the integrated circuit device 100 may include a substrate 102 including a first device region AX and a second device region BX, and first through fourth fin-type active regions F1 through F4 protruding from the first device region AX and the second device region BX of the substrate 102 in a vertical direction (e.g., a Z direction).

The first through fourth fin-type active regions F1 through F4 may include a first fin-type active region F1 and a third fin-type active region F3 protruding from the first device region AX of the substrate 102 in the vertical direction (e.g., the Z direction), and a second fin-type active region F2 and a fourth fin-type active region F4 protruding from the second device region BX of the substrate 102 in the vertical direction (e.g., the Z direction). A width in a second horizontal direction (e.g., a Y direction) of each of the first fin-type active region F1 and the third fin-type active region F3 may be the same or substantially the same as each other. In addition, a width in a second horizontal direction (e.g., the Y direction) of each of the second fin-type active region F2 and the fourth fin-type active region F4 may be the same or substantially the same as each other. In addition, a width in the second horizontal direction (e.g., the Y direction) of the first fin-type active region F1 may be less than a width in the second horizontal direction (e.g., the Y direction) of the second fin-type active region F2. The first fin-type active region F1 may extend parallel with the third fin-type active region F3 in a first horizontal direction (e.g., an X direction). In addition, the second fin-type active region F2 and the fourth fin-type active region F4 may extend in parallel with each other in the first horizontal direction (e.g., the X direction).

In FIG. 1, one first fin-type active region F1 and one third fin-type active region F3 arranged in the first device region AX, and one second fin-type active region F2 and one fourth fin-type active region F4 arranged in the second device region BX are illustrated, but more fin-type active regions may also be arranged in each of the first device region AX and the second device region BX.

The substrate 102 may include a semiconductor such as Si and Ge, or a compound semiconductor such as SiGe, SiC, GaAs, InAs, InGaAs, and InP. The terms “SiGe”, “SiC”, “GaAs”, “InAs”, “InGaAs”, and “InP” used in the present inventive concept may be referred to as materials including elements included in each term, but might not be referred to as chemical formulas representing a stoichiometric relationship. The substrate 102 may include a conductive region, for example, a well doped with impurities or a structure doped with impurities.

A device isolation layer 112 covering sidewalls of each of the first through fourth fin-type active regions F1 through F4 may be arranged on the substrate 102. The device isolation layer 112 may include, for example, an oxide layer, a nitride layer, or a combination thereof. In the first device region AX and the second device region BX, the first through fourth fin-type active regions F1 through F4 may protrude in a fin shape from the substrate 102.

A first gate line 161 may extend long in the second horizontal direction (e.g., the Y direction) crossing the first horizontal direction (e.g., the X direction) on the first fin-type active region F1 and the third fin-type active region F3. In addition, a second gate line 162 may extend long in the second horizontal direction (e.g., the Y direction) on the second fin-type active region F2 and the fourth fin-type active region F4. In some embodiments of the present inventive concept, a width in the first horizontal direction (e.g., the X direction) of the first gate line 161 may be less than a width in the first horizontal direction (e.g., the X direction) of the second gate line 162.

In regions, where the first through fourth fin-type active regions F1 through F4 cross the first and second gate lines 161 and 162, first and second nanosheet stacks NSS1 and NSS2 may be arranged on a fin top surface FT of each of the first through fourth fin-type active regions F1 through F4. In the regions, where the first fin-type active region F1 and the third fin-type active region F3 cross the first gate line 161, the first nanosheet stack NSS1 may be arranged on the fin top surface FT of each of the first fin-type active region F1 and the third fin-type active region F3. In addition, in the regions, where the second fin-type active region F2 and the fourth fin-type active region F4 cross the second gate line 162, the second nanosheet stack NSS2 may be arranged on the fin top surface FT of each of the second fin-type active region F2 and the fourth fin-type active region F4.

The first and second nanosheet stacks NSS1 and NSS2 may face the fin top surface FT at positions where they are spaced apart from the first through fourth fin-type active regions F1 through F4 in the vertical direction (e.g., the Z direction). The term “nanosheet” used in the present inventive concept may be referred to as a conductive structure having a cross-section substantially perpendicular to a direction in which a current flows. The nanosheet should be understood to include nanowires.

The first and second nanosheet stacks NSS1 and NSS2 may include a plurality of nanosheets mutually overlapping on the fin top surface FT of each of the first through fourth fin-type active regions F1 through F4. The first nanosheet stack NSS1 may be arranged on the first fin-type active region F1 and the third fin-type active region F3. The second nanosheet stack NSS2 may be arranged on the second fin-type active region F2 and the fourth fin-type active region F4.

The first nanosheet stack NSS1 may include a first short nanosheet N1_1, a second short nanosheet N2_1, and a third short nanosheet N3_1. The second nanosheet stack NSS2 may include a first long nanosheet N1_2, a second long nanosheet N2_2, and a third long nanosheet N3_2. In this case, vertical distances (e.g., Z direction distances) from the fin top surface FT, of the first short nanosheet N1_1, the second short nanosheet N2_1, and the third short nanosheet N3_1 may be different from each other. In addition, vertical distances (e.g., Z direction distances) from the fin top surface FT, of the first long nanosheet N1_2, the second long nanosheet N2_2, and the third long nanosheet N3_2 may be different from each other. In some embodiments of the present inventive concept, a width, in the second horizontal direction (e.g., the Y direction), of the first nanosheet stack NSS1 may be less than a width, in the second horizontal direction (e.g., the Y direction), of the second nanosheet stack NSS2.

The number of each of the first and second nanosheet stacks NSS1 and NSS2, and the number of each of the first and second gate lines 161 and 162 arranged on each one of the first through fourth fin-type active regions F1 through F4 are not particularly limited. For example, on each one of the first through fourth fin-type active regions F1 through F4, one set or a plurality of sets of the first and second nanosheet stacks NSS1 and NSS2 and one set or a plurality of sets of the first and second gate lines 161 and 162 may be arranged.

In FIGS. 2A and 2B, each of the first and second nanosheet stacks NSS1 and NSS2 is illustrated to include three nanosheets, but the present inventive concept is not limited thereto. For example, each of the first and second nanosheet stacks NSS1 and NSS2 may also include one, two, or four or more nanosheets. Each of the first through third short nanosheets N1_1 through N3_1 and the first through third long nanosheets N1_2 through N3_2 may include a channel region. For example, each of the first through third short nanosheets N1_1 through N3_1 and the first through third long nanosheets N1_2 through N3_2 may have a thickness in a range of about 4 nm to about 6 nm, but the present inventive concept is not limited thereto. In this case, the thickness of each of the first through third short nanosheets N1_1 through N3_1 and the first through third long nanosheets N1_2 through N3_2 may mean a magnitude thereof in the vertical direction (e.g., the Z direction). In some embodiments of the present inventive concept, the first through third short nanosheets N1_1 through N3_1 and the first through third long nanosheets N1_2 through N3_2 may have substantially the same thickness as each other in the vertical direction (e.g., the Z direction) In some embodiments of the present inventive concept, at least some of the first through third short nanosheets N1_1 through N3_1 and the first through third long nanosheets N1_2 through N3_2 may have different thicknesses from each other in the vertical direction (e.g., the Z direction).

As illustrated in FIGS. 2A and 2B, the first through third short nanosheets N1_1 through N3_1 included in one of the first and second nanosheet stacks NSS1 and NSS2 may have the same size as each other in the first horizontal direction (e.g., the X direction). The first through third long nanosheets N1_2 through N3_2 may have the same size as each other in the first horizontal direction (e.g., the X direction). In this case, the first through third short nanosheets N1_1 through N3_1 and the first through third long nanosheets N1_2 through N3_2 may have different sizes from each other in the first horizontal direction (e.g., the X direction). In some embodiments of the present inventive concept, at least some of the first through third short nanosheets N1_1 through N3_1 included in the first nanosheet stack NSS1 may have different sizes from each other. For example, a length of each of the first short nanosheet N1_1 and the second short nanosheet N2_1, which are relatively closer to the fin top surface FT, among the first through third short nanosheets N1_1 through N3_1 in the first horizontal direction (e.g., the X direction) may be less than a length of the third short nanosheet N3_1 which is farthest from the fin top surface FT among the first through third short nanosheets N1_1 through N3_1.

A plurality of first source/drain regions SD1 may be formed in the first device region AX, and a plurality of second source/drain regions SD2 may be formed in the second device region BX. In some embodiments of the present inventive concept, a width in the first horizontal direction (e.g., the X direction) of the plurality of first source/drain regions SD1 may be less than a width in the first horizontal direction (e.g., the X direction) of the plurality of second source/drain regions SD2.

In the first device region AX, a plurality of first gate lines 161 may extend long in the second horizontal direction (e.g., the Y direction) on the first and third fin-type active regions F1 and F3 and the device isolation layer 112. In the second device region BX, a plurality of second gate lines 162 may extend long in the second horizontal direction (e.g., the Y direction) on the second and fourth fin-type active regions as F2 and F4 and the device isolation layer 112. Each of the first and second gate lines 161 and 162 may cover the first and second nanosheet stacks NSS1 and NSS2 and surround each of the first through third short nanosheets N1_1 through N3_1 and the first through third long nanosheets N1_2 through N3_2 on the first through fourth fin-type active regions F1 through F4. On the substrate 102, a plurality of NMOS transistors TR1 and a plurality of PMOS transistors TR2 may be formed at portions where the first through fourth fin-type active regions F1 through F4 cross the first and second gate lines 161 and 162.

In some embodiments of the present inventive, the first device region AX may include an n-channel (N) metal-oxide-semiconductor (MOS) (NMOS) transistor region, and the second device region BX may include a p-channel (P) MOS (PMOS) transistor region. The plurality of NMOS transistors TR1 may be formed at portions, where the first fin-type active region F1 crosses the first and second gate lines 161 and 162 in the first device region AX, and the plurality of PMOS transistors TR2 may be formed at portions where the second fin-type active region F2 crosses the first and second gate lines 161 and 162 in the second device region BX.

In some embodiments of the present inventive concept, the first gate line 161 may include a first main gate portion 161M and a plurality of sub-gate portions 161S. In addition, the second gate line 162 may include a second main gate portion 162M and a plurality of second sub-gate portions 162S. The first and second main gate portions 161M and 162M may cover an upper surface of the first nanosheet stack NSS1 and the second nanosheet stack NSS2, and extend long in the second horizontal direction (e.g., the Y direction). The first and second sub-gate portions 161S and 162S may be connected to the first and second main gate portions 161M and 162M in one body, respectively, and each one of the first and second sub-gate portions 161S and 162S may be arranged between each of the first through third short nanosheets N1_1 through N3_1 and the first through third long nanosheets N1_2 through N3_2, between the first and third fin-type active region F1 and F3 and the first short nanosheet N1_1, and between the second and fourth fin-type active region F2 and F4 and the first long nanosheet N1_2. For example, the first sub-gate portions 161S may be disposed between each of the first through third short nanosheets N1_1 through N3_1 and between the first and third fin-type active region F1 and F3 and the first short nanosheet N1_1. For example, the second sub-gate portions 162S may be disposed between each of the first through third long nanosheets N1_2 through N3_2 and between the second and fourth fin-type active region F2 and F4 and the first long nanosheet N1_2. For example, the third short nanosheet N3_1 may be disposed between an uppermost first sub-gate portion 161S and the first main gate portion 161M, and the third long nanosheet N3_2 may be disposed between an uppermost second sub-gate portion 162S and the second main gate portion 162M.

Each of the first and second gate lines 161 and 162 may include, for example, a metal, metal nitride, metal carbide, or a combination thereof. The metal may include at least one of, for example, Ti, W, Ru, Nb, Mo, Hf, Ni, Co, Pt, Yb, Tb, Dy, Er, and Pd. The metal nitride may include one of TiN and/or TaN. The metal carbide may include TiAlC.

The term “vertical level” used in the present specification may indicate a height in the vertical direction (e.g., the Z direction or-Z direction) from an upper surface of the substrate 102.

A gate dielectric layer 152 may be arranged between the first through third short nanosheets N1_1 through N3_1 and a gate line 160, and between the first through third long nanosheets N1_2 through N3_2 and the gate line 160. The gate dielectric layer 152 may include portions covering a surface of each of the first through third short nanosheets N1_1 through N3_1 and the first through third long nanosheets N1_2 through N3_2, and portions covering sidewalls of the first and second main gate portions 161M and 162M.

In some embodiments of the preset inventive concept, the gate dielectric layer 152 may have a stacked structure of an interface layer and a high dielectric layer. The interface layer may include a low dielectric material layer having a dielectric constant of about 9 or less, for example, a silicon oxide layer, a silicon oxynitride layer, or a combination thereof. In some embodiments of the present inventive concept, the interface layer may be omitted. The high-k dielectric layer may include a material having a dielectric constant greater than that of the silicon oxide layer. For example, the high dielectric layer may have a dielectric constant of about 10 to about 25. The high-k dielectric layer may include hafnium oxide, but the present inventive concept is not limited thereto.

In some embodiments of the present inventive concept, the first through third short nanosheets N1_1 through N3_1 and the first through third long nanosheets N1_2 through N3_2 may include semiconductor layers including substantially the same elements as each other. In an example, each of the first through third short nanosheets N1_1 through N3_1 and the first through third long nanosheets N1_2 through N3_2 may include a Si layer. In the first device region AX, the first through third short nanosheets N1_1 through N3_1 may be doped with a dopant of the same conductivity type as the conductivity type of the first source/drain region SD1. In the second device region BX, the first through third long nanosheets N1_2 through N3_2 may be doped with a dopant of the same conductivity type as the conductivity type of the second source/drain region SD2. For example, in the first device region AX, the first through third short nanosheets N1_1 through N3_1 may include an Si layer doped with an n-type dopant, and in the second device region BX, the first through third long nanosheets N1_2 through N3_2 may include an Si layer doped with a p-type dopant.

Both sidewalls of each of the first and second gate lines 161 and 162 may be covered by a plurality of outer insulating spacers 118 on the first through fourth fin-type active regions F1 through F4 and the device isolation layer 112. The plurality of outside insulating spacers 118 may cover both sidewalls of the first and second main gate portions 161M and 162M on the upper surfaces of the first and second nanosheet stacks NSS1 and NSS2. Each of the plurality of outer insulating spacers 118 may be spaced apart from the gate line 160 with the gate dielectric layer 152 therebetween. The plurality of outside insulating spacers 118 may include, for example, silicon nitride, silicon oxide, SiCN, SiBN, SiON, SiOCN, SiBCN, SiOC, or a combination thereof. The terms “SiCN”, “SiBN”, “SiON”, “SiOCN”, “SiBCN”, and “SiOC” used in the present inventive concept may be referred to as materials including elements included in each term, but might not be referred to as chemical formulas representing a stoichiometric relationship.

As illustrated in FIG. 2A, in the first device region AX, a plurality of inner insulating spacers may be arranged between each of the first through third short nanosheets N1_1 through N3_1, between the first fin-type active region F1 and the first short nanosheet N1_1, and between the plurality of first sub-gate portions 161S and the first source/drain region SD1. In the first device region AX, both sidewalls of each of the plurality of first sub-gate portions 161S may be covered by an inner side insulating spacer with the gate dielectric layer 152 therebetween. In the first device region AX, each of the plurality of sub-gate portions 161S may be spaced apart from the first source/drain region SD1 with the gate dielectric layer 152 and an inner side insulating spacer disposed therebetween. Each of the plurality of inner side insulating spacers may contact the first source/drain region SD1. At least some of the plurality of inner side insulating spacers may overlap the outer insulating spacer 118 in the vertical direction (e.g., the Z direction). The inner side insulating spacer may include, for example, silicon nitride, silicon oxide, SiCN, SiBN, SiON, SiOCN, SiBCN, SiOC, or a combination thereof. The inner side insulating spacer may further include an air gap. In some embodiments of the present inventive concept, the inner side insulating spacer may include the same material as the outer insulating spacer 118. In some embodiments of the present inventive concept, the outside insulating spacer 118 and the inner side insulating spacer may include different materials from each other.

In the first device region AX, each of the plurality of first source/drain regions SDI may face the plurality of first sub-gate portions 161S in the first horizontal direction (e.g., the X direction) with the inner side insulating spacers disposed therebetween. The plurality of first source/drain regions SD1 might not include portions contacting the gate dielectric layer 152.

As illustrated in FIG. 2A, in the second device region BX, between each of the first through third long nanosheets N1_2 through N3_2 and between the second fin-type active region F2 and the first long nanosheet N1_2, both sidewalls of each of the plurality of second sub-gate portions 162S may be spaced apart from the second source/drain region SD2 with the gate dielectric layer 152 disposed therebetween. The gate dielectric layer 152 may include a portion contacting the second source/drain region SD2. Each of the plurality of second source/drain regions SD2 may face the second nanosheet stack NSS2 and the plurality of second sub-gate portions 162S in the first horizontal direction (e.g., the X direction).

In some embodiments of the present inventive concept, each of the first and second gate lines 161 and 162 may have a structure in which a metal nitride layer, a metal layer, a conductive capping layer, and a gap-fill metal layer are sequentially stacked. For example, the metal nitride layer and the metal layer may include at least one metal of Ti, Ta, W, Ru, Nb, Mo, and Hf. For example, the gap-fill metal layer may include a W layer or an Al layer. Each of the first and second gate lines 161 and 162 may include at least one work function metal-including layer. For example, the at least one work function metal-including layer may include at least one metal of Ti, W, Ru, Nb, Mo, Hf, Ni, Co, Pt, Yb, Tb, Dy, Er, and Pd. In some embodiments of the present inventive concept, each of the first and second gate lines 161 and 162 may have a stacked structure of TiAlC/TiN/W, a stacked structure of TiN/TaN/TiAlC/TiN/W, or a stacked structure of TiN/TaN/TiN/TiAlC/TiN/W, but the present inventive concept is not limited thereto.

As illustrated in FIGS. 2A and 2B, the gate dielectric layer 152 covering the first and second gate lines 161 and 162 and sidewalls of the first and second gate lines 161 and 162 may be covered by capping insulating patterns 164 and 165. The capping insulating pattern 164 may include, for example, a silicon nitride layer.

In the first device region AX, the first main gate portion 161M of the first gate line 161 may be spaced apart from the first source/drain region SD1 with the outer insulating spacer 118 disposed therebetween. In the second device region BX, the second main gate portion 162M of the second gate line 162 may be spaced apart from the second source/drain region SD2 with the outer insulating spacer 118 disposed therebetween.

In some embodiments of the present inventive concept, the first device region AX may include the NMOS transistor region, and the second device region BX may include the PMOS transistor region. In this case, the plurality of first source/drain regions SD1 in the first device region AX may include an Si layer doped with an n-type dopant or an SiC layer doped with an n-type dopant, and the plurality of second source/drain regions SD2 in the second device region BX may include an SiGe layer doped with a p-type dopant. The n-type dopant may include phosphorus (P), arsenic (As), or antimony (Sb). The p-type dopant may include boron (B) or gallium (Ga).

The plurality of first source/drain regions SD1 in the first device region AX may have different shapes and sizes from those of the plurality of second source/drain regions SD2 in the second device region BX. However, the present inventive concept is not limited thereto, and the plurality of first and second source/drain regions SD1 and SD2 may have various shapes and sizes in the first device region AX and the second device region BX, respectively.

The plurality of outer insulating spacers 118 may be covered by an inter-gate insulating layer 144 in the first device region AX and the second device region BX. The inter-gate insulating layer 144 may include, for example, a silicon nitride layer, a silicon oxide layer, SiON, SiOCN, or a combination thereof.

The plurality of capping insulating patterns 164 and the inter-gate insulating layer 144 disposed between each of the plurality of capping insulating patterns 164 may be covered by an insulating structure 190. The insulating structure 190 may include an etching stop layer 190A and an inter-layer insulating layer 190B. The etching stop layer 190A may include, for example, silicon carbide (SiC), SiN, nitrogen-doped silicon carbide (SiC:N), SiOC, AlN, AlON, AlO, AlOC, or a combination thereof. The inter-layer insulating layer 190B may include an oxide layer, a nitride layer, an ultra low k (ULK) layer having an ultra low dielectric constant K of about 2.2 to about 2.4, or a combination thereof. For example, the inter-layer insulating layer 190B may, for example, include a tetra-ethyl-ortho-silicate (TEOS) layer, a high density plasma (HDP) layer, a boro-phospho-silicate glass (BPSG) layer, a flowable chemical vapor deposition (FCVD) oxide layer, an SiON layer, an SiOC layer, an SiCOH layer, or a combination thereof.

As illustrated in FIGS. 2A and 2B, in the first device region AX, a plurality of first source/drain contacts 175 may be formed on the plurality of first source/drain regions SD1. In addition, in the second device region BX, a plurality of second source/drain contacts 174 and a plurality of source/drain via contacts 192 may be formed on the plurality of second source/drain regions SD2. The plurality of second source/drain regions SD2 may be connected to a conductive line disposed above source/drain via contacts 192 via the plurality of second source/drain contacts 174 and the plurality of source/drain via contacts 192. In some embodiments of the present inventive concept, the length of the plurality of first source/drain contacts 175 in the vertical direction (e.g., the Z direction) may be less than the length of the plurality of second source/drain contacts 174 in the vertical direction (e.g., the Z direction). In some embodiments of the present inventive concept, a vertical level of a lowermost surface of the plurality of first source/drain contacts 175 may be higher than a vertical level of a lowermost surface of the plurality of second source/drain contacts 174.

Each of the plurality of first source/drain contacts 175 and the plurality of second source/drain contacts 174 may penetrate the inter-gate insulating layer 144 in the vertical direction (e.g., the Z direction), and may contact each of the first source/drain region SD1 and the second source/drain region SD2, respectively. The plurality of source/drain via contacts 192 may penetrate the insulating structure 190 in the vertical direction (e.g., the Z direction), and contact an upper surface of the second source/drain contact 174.

The plurality of first source/drain contacts 175 may include a first conductive barrier layer 175A and a short metal plug 175B. The plurality of second source/drain contacts 174 may include a second conductive barrier layer 174A and first and second long metal plugs 174B and 174C. The plurality of source/drain via contacts 192 may include a conductive barrier layer 192A and a metal plug 192B. The first conductive barrier layer 175A, a second conductive barrier layer 174A, and the conductive barrier layer 192A may include, for example, Ti, Ta, TiN, TaN, or a combination thereof. The short metal plug 175B, the first and second long metal plugs 174B and 174C, and the metal plug 192B may include, for example, W, Co, Cu, Ru, Mn, or a combination thereof, but the present inventive concept not limited thereto.

In some embodiments of the present inventive concept, sidewalls of each of the plurality of first source/drain contacts 175, the plurality of second source/drain contacts 174, and the plurality of source/drain via contacts 192 may be surrounded by a contact insulating spacer. The contact insulating spacer may include, for example, SiCN, SiCON, SiN, or a combination thereof, but the present inventive concept is not limited thereto.

A gate contact may be formed on an upper portion of each of the first and second gate lines 161 and 162. Each of the first and second gate lines 161 and 162 may be connected to a conductive line thereon via the gate contact. The gate contact may have a structure similar to that described above with respect to the plurality of first source/drain contacts 175, the plurality of second source/drain contacts 174, and the source/drain via contact 192.

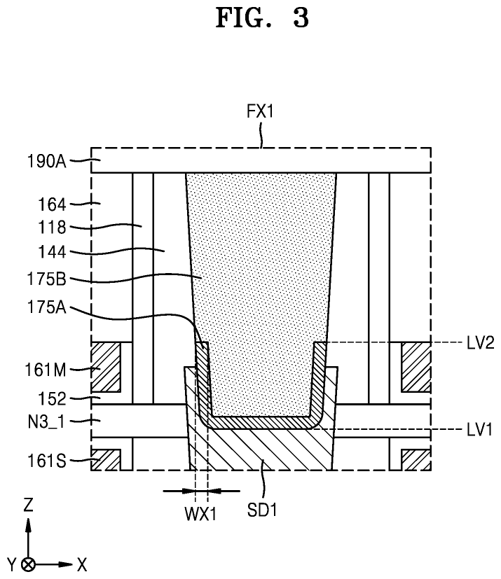

FIG. 3 is an enlarged cross-sectional view of a region FX1 in FIG. 1. Descriptions already given with reference to FIGS. 1A, 2A, and 2B are briefly given or omitted.

Referring to FIG. 3, the first conductive barrier layer 175A of the plurality of first source/drain contacts 175 may at least partially surround a portion of the sidewalls of the short metal plug 175B. The first conductive barrier layer 175A may at least partially surround lower sidewalls and the lowermost surface of the short metal plug 175B. A vertical level LV2 of an uppermost surface of the first conductive barrier layer 175A may be higher than a vertical level of an uppermost surface of at least one of the first short nanosheets N1_1.

In addition, in some embodiments of the present inventive concept, the vertical level LV2 of the uppermost surface of the first conductive barrier layer 175A may be higher than or equal to a vertical level of an uppermost surface of the first gate line 161. Although the vertical level LV2 of the uppermost surface of the first conductive barrier layer 175A is illustrated the same as the vertical level of an uppermost surface of the first main gate portion 161M, the vertical level LV2 of the uppermost surface of the first conductive barrier layer 175A may be higher than the vertical level of the uppermost surface of the first main gate portion 161M.

A vertical level LV1 of a lowermost surface of the first conductive barrier layer 175A may be lower than a vertical level of an uppermost surface of the first source/drain region SD1. In addition, the lowermost surface of the first conductive barrier layer 175A may be arranged inside the first source/drain region SD1. The first conductive barrier layer 175A may at least partially surround a portion of sidewalls of the short metal plug 175B. In this case, the other portion of the sidewalls of the short metal plug 175B may be surrounded by the inter-gate insulating layer 144 and not the first conductive barrier layer 175A. For example, the first conductive barrier layer 175A may contact a lower portion of the sidewalls of the short metal plug 175B, and the inter-gate insulating layer 144 may contact an upper portion of the sidewalls of the short metal plug 175B.

By forming the plurality of first source/drain contacts 175 while the first conductive barrier layer 175A at least partially surrounds a portion of the sidewalls of the short metal plug 175B, resistance of the plurality of first source/drain contacts 175 may be reduced. In this manner, the reliability and stability of the integrated circuit device 100 may be increased.

In some embodiments of the present inventive concept, the first conductive barrier layer 175A may be arranged between the first source/drain region SD1 and the short metal plug 175B. The first conductive barrier layer 175A may conformally cover the lowermost surface of the short metal plug 175B

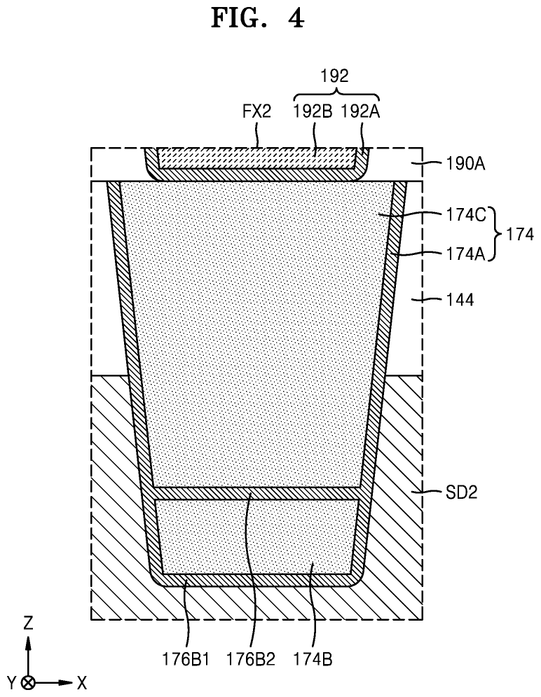

FIG. 4 is an enlarged cross-sectional view of a region FX2 in FIG. 1.

Referring to FIG. 4, the second conductive barrier layer 174A of the second source/drain contact 174 may at least partially surround sidewalls of the first and second long metal plugs 174B and 174C. The second conductive barrier layer 174A may at least partially surround the sidewalls and lower surfaces of the first and second long metal plugs 174B and 174C. In addition, the second conductive barrier layer 174A may include a first lower portion layer 176B1 and a second lower portion layer 176B2. The first lower portion layer 176B1 may cover a lowermost surface of the first long metal plug 174B. The second lower portion layer 176B2 may extend in the first horizontal direction (e.g., the X direction) on the first lower portion layer 176B1.

In some embodiments of the present inventive concept, the first long metal plug 174B may be arranged and/or interposed between the first lower portion layer 176B1 and the second lower portion layer 176B2. In addition, all sidewalls of the first long metal plugs 174B may be surrounded by the second conductive barrier layer 174A. In addition, in some embodiments of the present inventive concept, the second long metal plug 174C may be arranged on the second lower portion layer 176B2, and the sidewalls of the second long metal plug 174C may be surrounded by the second conductive barrier layer 174A. The first long metal plug 174B may be arranged inside the second source/drain region SD2. In other words, vertical levels of the first lower portion layer 176B1 and the second lower portion layer 176B2 may be lower or equal to an uppermost surface of a second source/drain SD2.

By forming the first lower portion layer 176B1 and the second lower portion layer 176B2 with respect to the plurality of second source/drain contacts 174, a leakage current of the plurality of second source/drain contacts 174 may be prevented, and the stability of the integrated circuit device 100 may be secured.

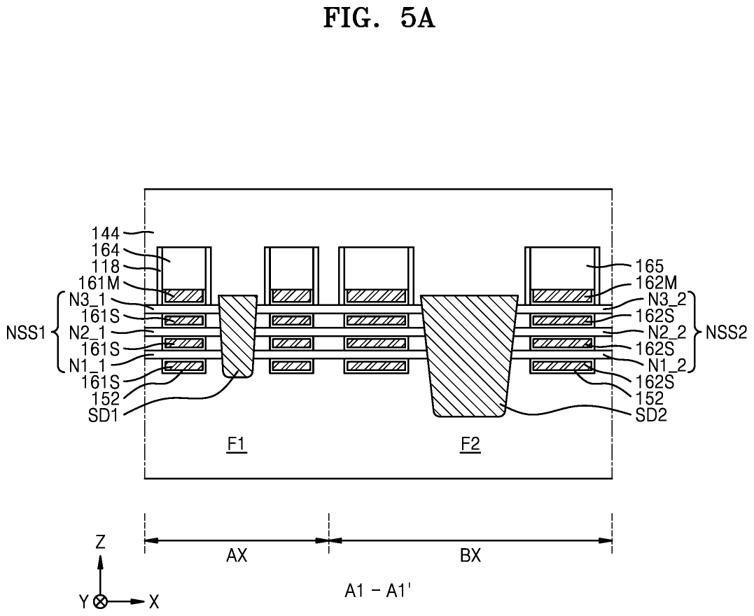

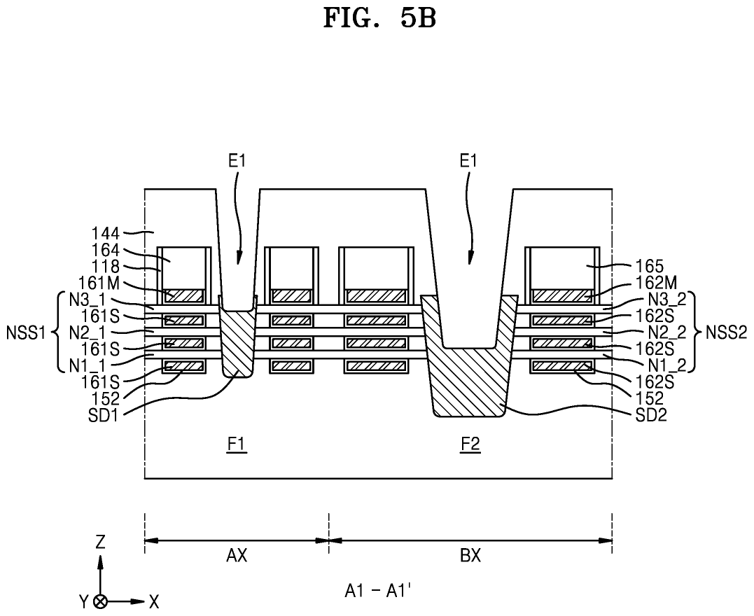

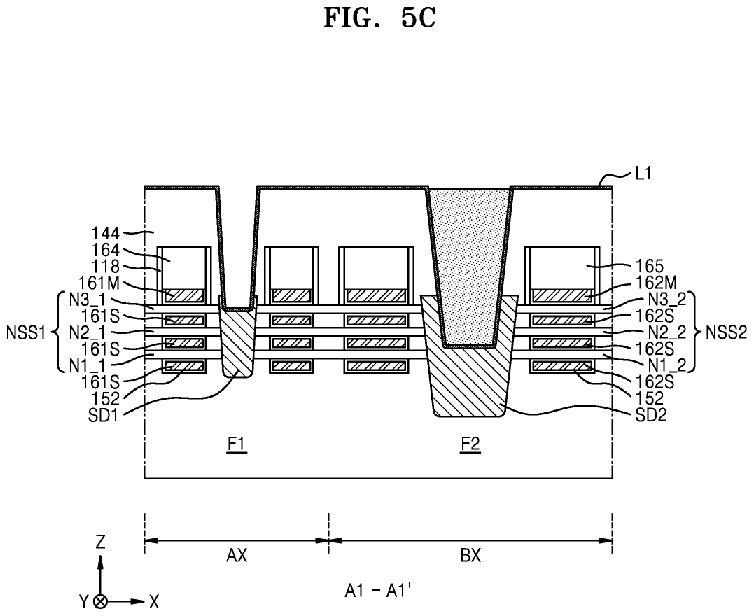

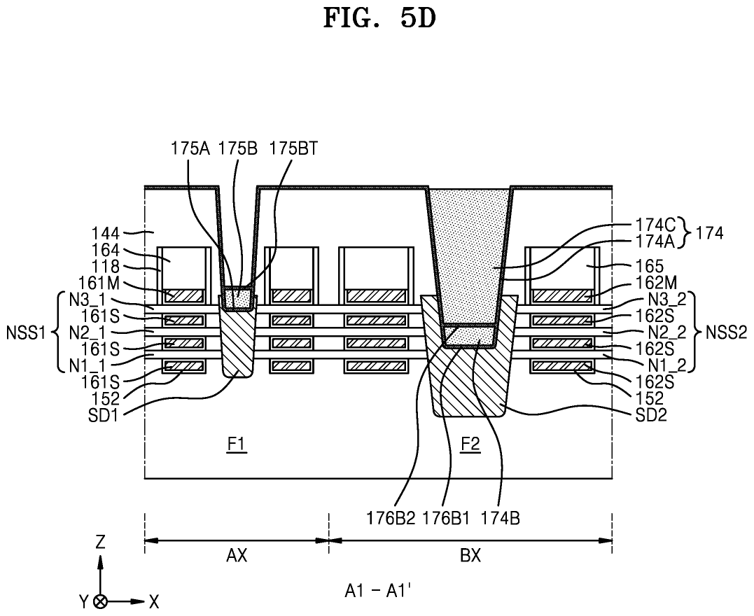

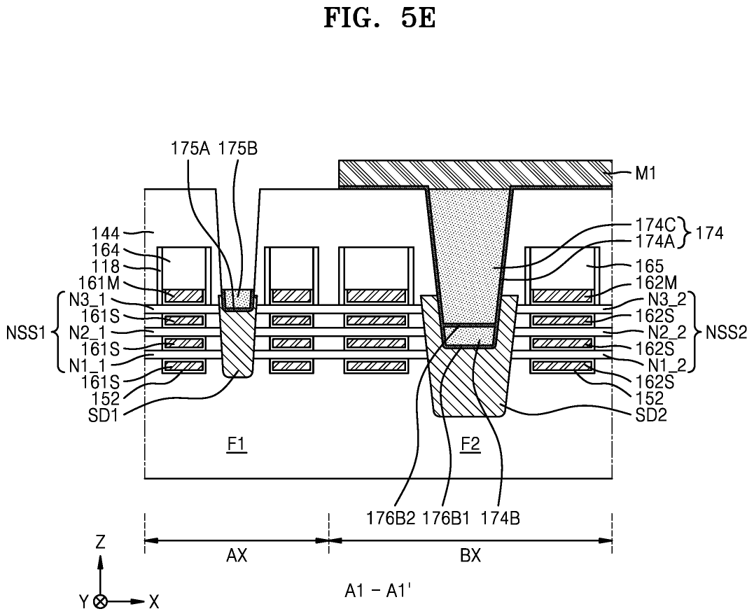

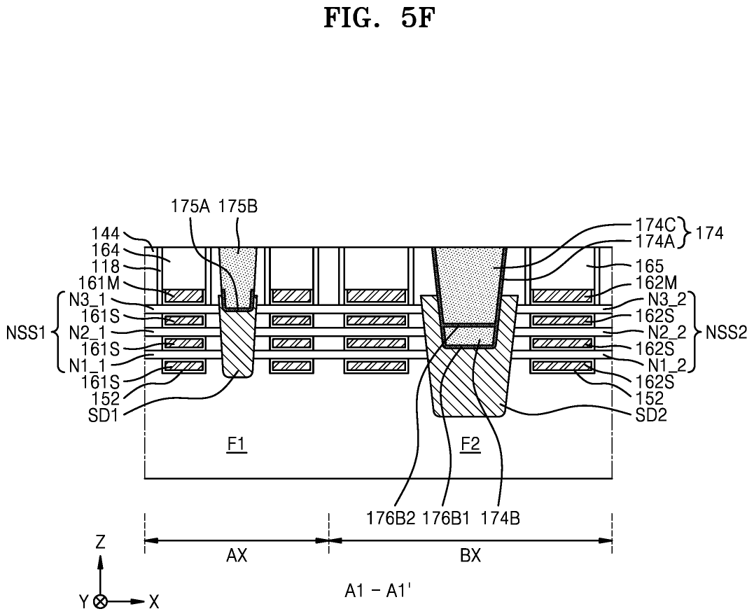

FIGS. 5A through SF are cross-sectional views for describing a method of manufacturing the integrated circuit device 100, according to embodiments of the present inventive concept.

Referring to FIG. 5A, in the integrated circuit device 100, firstly, the first and second gate lines 161 and 162, the first and second nanosheet stacks NSS1 and NSS2, the gate dielectric layer 152, the capping insulating patterns 164 and 165, the inter-gate insulating layer 144, the plurality of outer insulating spacers 118, the first source/drain region SDI, and the second source/drain region SD2 may be formed on the first fin-type active region F1 and the second fin-type active region F2 of the substrate 110.

Referring to FIG. 5B, after certain processes are performed, by etching a portion of an inter-gate insulating layer 144 to form a source/drain contact to described below on each of the first source/drain region SD1 and the second source/drain region SD2, a contact hole El may be formed.

Referring to FIG. 5C, by applying a deposition process on the resultant product of FIG. 5B, a first barrier layer L1 may be conformally formed. The first barrier layer L1 may cover a portion of the first source/drain region SD1, a portion of the second source/drain region SD2, and the inter-gate insulating layer 144. Next, a long metal plug may fill the contact hole on the second source/drain region SD2.

Referring to FIG. 5D, after a certain etching process is performed, the short metal plug 175B and the first long metal plug 174B may be formed on the first source/drain region SD1 and the second source/drain region SD2. Next, a dummy barrier layer 175BT may be formed on the short metal plug 175B, and the second lower portion layer 176B2 may be formed on the first long metal plug 174B. After the dummy barrier layer 175BT and the second lower portion layer 176B2 are formed, the second long metal plug 174C may be formed on the second lower portion layer 176B2.

Referring to FIG. 5E, a mask M1 may be formed in the second device region BX, by performing an etching process on the first device region AX, the dummy barrier layer 175BT already formed may be removed. Referring to FIG. 5F, after the mask M1 is removed from the resultant product of FIG. 5E, a conductive material may be stacked on the resultant product of FIG. 5E with the mask M1 removed. Next, by removing an upper portion of the resultant product with the conductive material stacked thereon, the first short metal plug 175B may be formed. In a process of removing the upper portion of the resultant product with the conductive material stacked thereon, an upper portion of the inter-gate insulating layer 144 may be removed together, and an upper surface of the capping insulating patterns 164 and 165 may be exposed.

Referring to FIGS. 1, 2A, and 2B again, thereafter, by forming the insulating structure 190 and the plurality of source/drain via contacts 192, the integrated circuit device 100 according to embodiments of the present inventive concept may be completed.

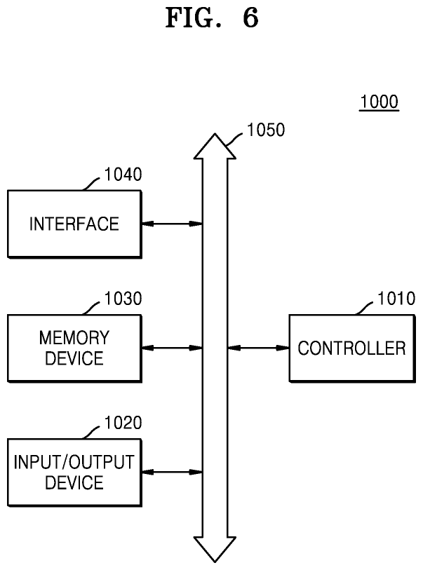

FIG. 6 is a configuration diagram of a system 1000 including an integrated circuit device, according to an embodiment of the present inventive concept.

Referring to FIG. 6, the system 1000 may include a controller 1010, an input/output device 1020, a memory device 1030, an interface 1040, and a bus 1050.

The system 1000 may include a mobile system or a system transceiving information. In some embodiments of the present inventive concept, the mobile system may include a portable computer, a web tablet, a mobile phone, a digital music player, or a memory card.

The controller 1010 may be used for controlling execution programs in the system 1000, and may include, for example, a micro-processor, a digital signal processor, a micro-controller, or a similar device.

The input/output device 1020 may be used to input or output data of the system 1000. The system 1000 may be connected to an external device, for example, a personal computer or a network by using the input/output device 1020, and may exchange data with the external device. The input/output device 1020 may include, for example, a touch screen, a touch pad, a keyboard, or a display.

The memory device 1030 may store data for an operation of the controller 1010, or may store data processed by the controller 1010. The memory device 1030 may include the integrated circuit device 100 according to embodiments of the present inventive concept described above.

The interface 1040 may include a data transmission path between the system 1000 and an external device. The controller 1010, the input/output device 1020, the memory device 1030, and the interface 1040 may communicate with each other via the bus 1050.

While the present inventive concept has been particularly shown and described with reference to example embodiments thereof, it will be apparent to those of ordinary skill in the art that various changes in form and detail may be made thereto without departing from the spirit and scope of the present inventive concept.

What is claimed is:

1. An integrated circuit device comprising:
a substrate including a first device region and a second device region;
a first fin-type active region and a third fin-type active region extending in a first horizontal direction in the first device region;
a second fin-type active region and a fourth fin-type active region extending in the first horizontal direction in the second device region;
a gate line extending in a second horizontal direction crossing the first horizontal direction in the first through fourth fin-type active regions;
a first source/drain region arranged adjacent to the gate line in the first fin-type active region;
a second source/drain region arranged adjacent to the gate line in the second fin-type active region;
a first source/drain contact extending in a vertical direction in the first device region, and connected to the first source/drain region, wherein the vertical direction is substantially perpendicular to the first horizontal direction and the second horizontal direction; and
a second source/drain contact extending in the vertical direction in the second device region, and connected to the second source/drain region;
wherein the first source/drain contact comprises a first short metal plug and a first conductive barrier layer at least partially surrounding a portion of sidewalls of the first short metal plug.

2. The integrated circuit device of claim 1,
wherein
the first conductive barrier layer is arranged between the first source/drain region and the short metal plug.

3. The integrated circuit device of claim 2, wherein a vertical level of an uppermost surface of the first conductive barrier layer is higher than a vertical level of an uppermost surface of the gate line.

4. The integrated circuit device of claim 1,
wherein the gate line comprises:
a first gate line extending in the second horizontal direction in the first device region; and
a second gate line extending in the second horizontal direction in the second device region,
wherein a width, in a first horizontal direction, of the first gate line is less than a width, in the first horizontal direction, of the second gate line.

5. The integrated circuit device of claim 1, wherein a width, in the first horizontal direction, of the first source/drain region is less than a width, in the first horizontal direction, of the second source/drain region.

6. The integrated circuit device of claim 5,
wherein the second source/drain contact comprises a long metal plug and a second conductive barrier layer, wherein the second conductive barrier layer surrounds sidewalls of the long metal plug, and
wherein the second conductive barrier layer comprises a first lower portion layer and a second lower portion layer, wherein the first lower portion layer covers a lowermost surface of the long metal plug, and the second lower layer extends in the first horizontal direction on the first lower portion layer.

7. The integrated circuit device of claim 6, wherein a vertical level of each of the first lower portion layer and the second lower portion layer of the second conductive barrier layer is lower than a vertical level of an uppermost surface of the second source/drain region.

8. The integrated circuit device of claim 1, wherein a length, in the vertical direction, of the first source/drain contact is less than a length, in the vertical direction, of the second source/drain contact.

9. The integrated circuit device of claim 1, further comprising a source/drain via contact extending in a vertical direction and disposed on the second source/drain contact in the second device region.

10. The integrated circuit device of claim 1,
further comprising an inter-gate insulating layer arranged in the first source/drain region,
wherein the first source/drain contact penetrates an uppermost surface in the first source/drain region, and
an upper portion of sidewalls of the first source/drain contact is at least partially surrounded by the inter-gate insulating layer.

11. An integrated circuit device comprising:
a substrate including a first device region and a second device region;
a first fin-type active region and a third fin-type active region extending in a first horizontal direction in the first device region;
a second fin-type active region and a fourth fin-type active region extending in the first horizontal direction in the second device region;
a gate line extending in a second horizontal direction crossing the first horizontal direction in the first through fourth fin-type active regions;
a first source/drain region arranged adjacent to the gate line in the first fin-type active region;
a second source/drain region arranged adjacent to the gate line in the second fin-type active region;
a first source/drain contact extending in a vertical direction in the first device region, and connected to the first source/drain region, wherein the vertical direction is substantially perpendicular to the first and second horizontal directions; and
a second source/drain contact extending in the vertical direction in the second device region, and connected to the second source/drain region;
wherein the first source/drain contact comprises a first short metal plug and a first conductive barrier layer at least partially surrounding a portion of sidewalls of the first short metal plug,
wherein the second source/drain contact comprises a long metal plug and a second conductive barrier layer at least partially surrounding sidewalls of the long metal plug,
wherein the gate line comprises a first gate line and a second gate line, wherein the first gate line extends in the second horizontal direction in the first device region, and the second gate line extends in the second horizontal direction in the second device region, and
wherein a width, in the first horizontal direction, of the first gate line is less than a width, in the first horizontal direction, of the second gate line.

12. The integrated circuit device of claim 11, further comprising:
a first nanosheet stack including at least one short nanosheet surrounded by the first gate line at a position spaced apart in the vertical direction from the first fin-type active region; and
a second nanosheet stack including at least one long nanosheet surrounded by the second gate line at a position spaced apart in the vertical direction from the second fin-type active region,
wherein a width, in a second horizontal direction, of the first nanosheet stack is less than a width, in the second horizontal direction, of the second nanosheet stack.

13. The integrated circuit device of claim 11, wherein a width, in the second horizontal direction, of the first fin-type active region is less than a width, in the second horizontal direction, of the second fin-type active region.

14. The integrated circuit device of claim 11,
wherein the second conductive barrier layer comprises a first lower portion layer and a second lower portion layer, wherein the first lower portion layer covers a lowermost surface of the long metal plug, and the second lower portion layer extends in the first horizontal direction on the first lower portion layer, and
wherein a vertical level of each of the first lower portion layer and the second lower portion layer of the second conductive barrier layer is lower than a vertical level of an uppermost surface of the second source/drain region.

15. The integrated circuit device of claim 14,
wherein the long metal plug comprises a first long metal plug and a second long metal plug,
wherein the first long metal plug is arranged between the first lower portion layer and the second lower portion layer, and sidewalls of the second long metal plug are surrounded by the second conductive barrier layer, and
wherein the second long metal plug is arranged on the second lower portion layer.

16. The integrated circuit device of claim 11, wherein a vertical level of a lowermost surface of the first source/drain contact is higher than a vertical level of a lowermost surface of the second source/drain contact.

17. The integrated circuit device of claim 11,
further comprising at least one first short nanosheet arranged in the first fin-type active region and surrounded by the first gate line,
wherein the first conductive barrier layer covers a lower surface of the first short metal plug, and
wherein a vertical level of an uppermost surface of the first conductive barrier layer is higher than or equal to a vertical level of an uppermost surface of the first gate line.

18. An integrated circuit device comprising:
a substrate including a first device region and a second device region;
a first fin-type active region and a third fin-type active region extending in a first horizontal direction in the first device region;
a second fin-type active region and a fourth fin-type active region extending in the first horizontal direction in the second device region;
a gate line extending in a second horizontal direction crossing the first horizontal direction in the first through fourth fin-type active regions and including a first gate line and a second gate line;
a first source/drain region arranged adjacent to the gate line in the first fin-type active region;
a second source/drain region arranged adjacent to the gate line in the second fin-type active region;
a first source/drain contact extending in a vertical direction in the first device region, and connected to the first source/drain region, wherein the vertical direction is substantially perpendicular to the first and second horizontal directions;
a second source/drain contact extending in the vertical direction in the second device region, and connected to the second source/drain region;
a first nanosheet stack including at least one short nanosheet surrounded by the first gate line at a position spaced apart in the vertical direction from the first fin-type active region; and
a second nanosheet stack including at least one long nanosheet surrounded by the second gate line at a position spaced apart in the vertical direction from the second fin-type active region,
wherein the first source/drain contact comprises a short metal plug and a first conductive barrier layer, wherein the first conductive barrier layer surrounds a portion of sidewalls of the short metal plug,
wherein the second source/drain contact comprises a long metal plug and a second conductive barrier layer, wherein the second conductive barrier layer surrounds sidewalls of the long metal plug,
wherein the first gate line extends in the second horizontal direction in the first device region, and the second gate line extends in the second horizontal direction in the second device region,
wherein a width, in the first horizontal direction, of the first gate line is less than a width, in the first horizontal direction, of the second gate line, and
wherein a width, in a second horizontal direction, of the first nanosheet is less than a width, in the second horizontal direction, of the second nanosheet stack.

19. The integrated circuit device of claim 18,
further comprising an inter-gate insulating layer arranged on the first source/drain region and the first nanosheet stack,
wherein the first conductive barrier layer contacts a lower surface of the short metal plug, and
wherein an upper portion of sidewalls of the first source/drain contact is at least partially surrounded by the inter-gate insulating layer.

20. The integrated circuit device of claim 18,
wherein the second conductive barrier layer comprises a first lower portion layer and a second lower portion layer, and wherein the long metal plug comprises a first long metal plug and a second long metal plug,
wherein the first long metal plug is arranged between the first lower portion layer and the second lower portion layer, and sidewalls of the second long metal plug are surrounded by the second conductive barrier layer,
wherein the second long metal plug is arranged on the second lower portion layer, and
wherein the first long metal plug and the second long metal plug comprise an identical material as each other.
